(19) United States
(12) Patent Application Publication
(10) Pub. No.: US 2017/0005259 A1
(43) Pub. Date: Jan. 5, 2017

(54) PIEZOELECTRIC DEVICE AND BASE

(71) Applicant: NIHON DEMPA KOGYO CO., LTD., Tokyo (JP)

(72) Inventor: Hiroaki MIZUMURA, SAITAMA (JP)

(73) Assignee: NIHON DEMPA KOGYO CO., LTD., Tokyo (JP)

(21) Appl. No.: 15/197,712

(22) Filed: Jun. 29, 2016

(30) Foreign Application Priority Data
Jul. 3, 2015 (JP) 2015-134331
Apr. 28, 2016 (JP) 2016-089970

(51) Int. Cl. H01L 41/29; H01L 41/313; H01L 41/047

(52) U.S. Cl. CPC H01L 41/29; H01L 41/0475; H01L 41/313; H01L 41/0477

(57) ABSTRACT

A piezoelectric device includes a crystal element, excitation electrodes, extraction electrodes, a base, and first and second wiring electrodes on the base and connected to the extraction electrodes. The crystal element is connectedly secured to the first wiring electrode with conductive adhesive at an end part at a side of the one side on one surface of the crystal element. The fixing and the wire bonding are performed such that a secured position with the conductive adhesive overlaps a bonding position on the crystal element side by the wire bonding in a crystal element thickness direction. The first wiring electrode is disposed at an end part at a side of one side of the base and has a planar shape and a size so as to planarly encompass at least a region formed by projecting a part where the conductive adhesive contacts the crystal element to the base side.

### CROSS-REFERENCE TO RELATED APPLICATIONS

This application is based on and claims priority under 35 U.S.C. §119 to Japanese Patent Application No. 2016-089970, filed on Apr. 28, 2016 and Japanese Patent Application No. 2015-134331, filed on Jul. 3, 2015, and the entire contents of which are incorporated herein by reference.

### TECHNICAL FIELD

This disclosure relates to a crystal unit as a piezoelectric device, a crystal controlled oscillator, and a base preferably used for fabricating the same.

### DESCRIPTION OF THE RELATED ART

Various pieces of electronic equipment such as mobile phones and personal computers often use a crystal unit and a crystal controlled oscillator to select and control a frequency or for a similar purpose.

For example, Japanese Unexamined Patent Application Publication No. 2010-147625 (hereinafter referred to as Patent Literature 1) discloses one example of a crystal unit. This crystal unit includes a crystal element, which has a rectangular shape in plan view, and a base. The crystal element includes excitation electrodes and extraction electrodes on both principal surfaces. The base includes this crystal element and has a first wiring electrode and a second wiring electrode connected to the above-described extraction electrodes. Bonding and securing the extraction electrode on one surface to the first wiring electrode on the base with a conductive adhesive secures the crystal element to the base. The position secured by the conductive adhesive is set at a part corresponding to an end part at a side of one side (specifically, one short side) of the crystal element and approximately center of this side. The extraction electrode disposed on the other surface of the crystal element is connected to the second wiring electrode on the base by wire bonding. Additionally, the bonding and the wire bonding are performed such that the secured position with the conductive adhesive and the bonding position on the crystal element side by the wire bonding overlap in a crystal element thickness direction.

In this crystal unit disclosed in Patent Literature 1, the crystal element is secured to the base at a part close to the approximate center of the short side and on the end part at a side of the short side, that is, the crystal element is secured at one site. Accordingly, Patent Literature 1 describes that the crystal element is less likely to be inclined, improving work efficiency (for example, see paragraph eight in Patent Literature 1). Additionally, one of the electrical connections between the crystal element and the base is performed by the wire bonding. This is considered to reduce an influence of stress from the secured portion of the crystal to the crystal element.

The wire bonding is performed on the extraction electrode formed on the crystal surface. Since the crystal is fragile, performing the wire bonding at a low force stably is important. To achieve this, it is important to reduce the inclination of the crystal element and to restrain a variation of a height of the crystal element (namely, a variation of a height of a bonding surface). Therefore, to secure the crystal element at one site with the conductive adhesive while the inclination and the variation of the height of the crystal element are further reduced, additional device is necessary.

A need thus exists for a piezoelectric device and a base which are not susceptible to the drawback mentioned above.

### SUMMARY

According to an aspect of this disclosure, there is provided a piezoelectric device includes a crystal element with a rectangular planar shape, excitation electrodes, extraction electrodes, a base, and a first wiring electrode and a second wiring electrode. The excitation electrodes are disposed on respective principal surfaces of the crystal element. The extraction electrodes are extracted from the respective excitation electrodes up to near one side of the crystal element. The base has a rectangular planar shape on which the crystal element is mounted. The first wiring electrode and the second wiring electrode are disposed on the base, the first second wiring electrode and the second wiring electrode are connected to the extraction electrodes. The crystal element is connectedly secured to the first wiring electrode with a conductive adhesive at an end part at a side of the one side on one principle surface of the crystal element. The extraction electrode is on another principle surface of the crystal element and the second wiring electrode are connected by a wire bonding. The connectedly secured and the wire bonding are performed such that a secured position with the conductive adhesive overlaps a bonding position on a side of the crystal element by the wire bonding in a crystal element thickness direction. The first wiring electrode is disposed at an end part at a side of one side of the base and has a planar shape and a size so as to planarly encompass at least a region formed by projecting a part where the conductive adhesive contacts the crystal element to a side of the base.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a plan view of a piezoelectric device 10 of an embodiment, and FIG. 1B is a sectional drawing of the piezoelectric device 10;

FIG. 2A is a plan view of main parts describing a relationship between a first wiring electrode and an applied region for conductive adhesive, FIG. 2B is a sectional drawing of the main parts, and FIG. 2C is a sectional drawing describing another bonded state;

FIG. 3 is a plan view describing a crystal element and is a drawing describing a relationship between the crystal element, an excitation electrode, and extraction electrodes;

FIG. 4A is a plan view describing a disclosure of a base, and FIG. 4B is a sectional drawing of the base;

FIG. 5A is a plan view describing another example (an example of mounting an oscillator circuit member) of a piezoelectric device and a base, FIG. 5B is a sectional drawing of the example, and FIG. 5C is a sectional drawing describing yet another example of a piezoelectric device and a base;

FIG. 6A is a plan view of a piezoelectric device that employs another embodiment of especially a first wiring electrode and a second wiring electrode, and FIG. 6B is a plan view focusing on these wiring electrodes;

FIG. 7A is a plan view of a piezoelectric device that employs yet another embodiment of especially a first wiring electrode and a second wiring electrode, and FIG. 7B is a plan view focusing on these wiring electrodes;

FIG. 8A is a plan view of the piezoelectric device 10 that employs another embodiment of especially a base, and FIG. 8B is a sectional drawing of the piezoelectric device; and

FIG. 9 is a drawing illustrating an example of a sheet-shaped base member.

### DETAILED DESCRIPTION

The following describes respective embodiments of the disclosure of this application with reference to the drawings. Each drawing used in the descriptions is merely illustrated schematically for understanding the disclosure. In each drawing used in the descriptions, like reference numerals designate corresponding or identical elements, and therefore such elements will not be further elaborated here. Shapes, dimensions, materials, and a similar factor described in the following embodiments are merely preferable examples within the scope of the disclosure. Therefore, the disclosure is not limited to only the following embodiments.

### 1. Embodiments of Piezoelectric Device

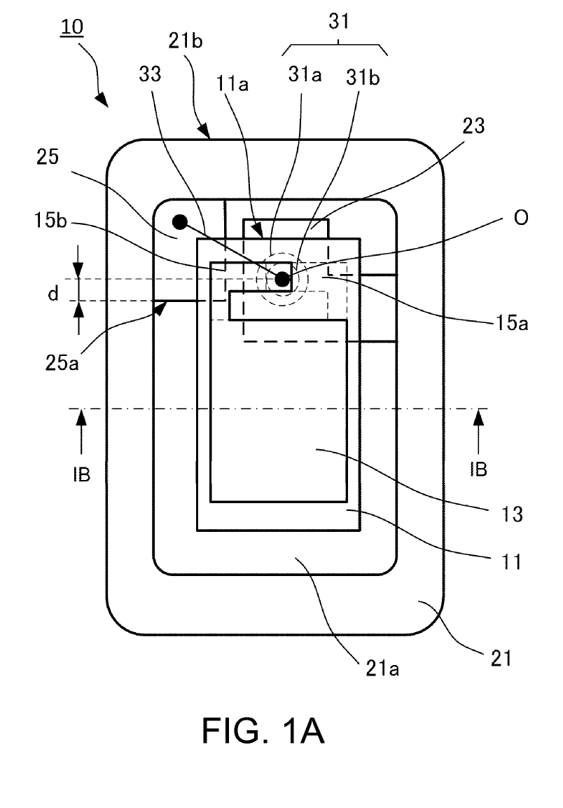

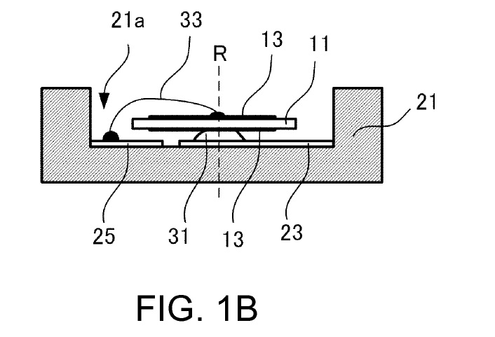

FIG. 1A is a plan view describing a piezoelectric device 10 of an embodiment of a first aspect. FIG. 1B is a sectional drawing of the piezoelectric device 10 taken along the line IB-IB in FIG. 1A. Note that this drawing omits the illustration of a lid provided to the piezoelectric device. The same applies to the following respective drawings.

The piezoelectric device 10 of the embodiment includes a crystal element 11, which has a rectangular shape in a planar shape, excitation electrodes 13, which are disposed on both principal surfaces of this crystal element 11, extraction electrodes 15a and 15b, a base 21, and a first wiring electrode 23 and a second wiring electrode 25. The extraction electrode 15a and the extraction electrode 15b are each extracted from the excitation electrodes 13 up to near one side 11a of the crystal element 11. The base 21 includes the crystal element 11 and has a rectangular shape in a planar shape. The first wiring electrode 23 and the second wiring electrode 25 are disposed on the base 21 and are connected to the extraction electrode 15a and the extraction electrode 15b. In this embodiment, the base 21 has a concave portion 21 a and includes the crystal element 11 inside this concave portion 21a. In this case, this base 21 is configured of a ceramic package.

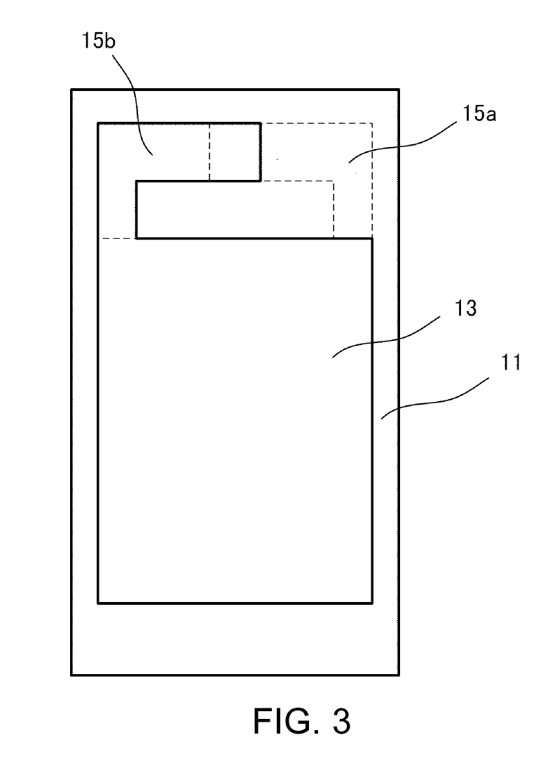

The crystal element 11 is connectedly secured to the first wiring electrode 23 with conductive adhesive 31 at an end part on the one side 11a side on one surface of the crystal element 11 and a part corresponding to approximate center in a direction along this one side 11a. Specifically, the crystal element 11 is held at one site, which is the end part on the one side (short side) 11a side of the crystal element 11 and is the approximately center portion of this side along this one side (short side) 11a with the conductive adhesive 31. For ease of understanding of the relationship between the crystal element 11, the excitation electrodes 13, the extraction electrode 15a and the extraction electrode 15b, FIG. 3 illustrates a plan view of the crystal element 11 alone including the crystal element 11, the excitation electrode 13, the extraction electrode 15a and the extraction electrode 15b. For example, silicone-based conductive adhesive is used as the conductive adhesive 31. The excitation electrode 13, the extraction electrode 15a and extraction electrode 15b can be each formed of, for example, laminated films of a chrome film and a gold film from the crystal element side.

The extraction electrode 15b, which is on the other surface of this crystal element 11, and the second wiring electrode 25 are connected with a wire 33 by wire bonding. The fixing (connectedly secured) with the conductive adhesive and the wire bonding are performed such that the secured position with the conductive adhesive 31 overlaps the bonding position on the crystal element side with the wire 33 by the wire bonding in the crystal element 11 thickness direction (a direction along a line segment R in FIG. 1B) (includes the case where the secured position and the bonding position almost overlap).

The wire bonding method is not especially limited, and a method such as a ball bonding method and a wedge bonding method can be used.

Furthermore, the first wiring electrode 23 is disposed at an end part on one side 21b (see FIG. 1A) side of the base 21 inside the concave portion 21a in the base 21 and at a part including a part corresponding to a center in a direction along this one side 21b. More specifically, the first wiring electrode 23 is disposed on the base 21 such that a part to which the conductive adhesive 31 is to be applied in the first wiring electrode 23 becomes a part corresponding to the above-described approximate center of the short side of the base 21 in the concave portion 21a of the base 21 and the part further extends to a direction opposite from the second wiring electrode 25 from this approximately center portion. The first wiring electrode 23 is, for example, extended up to below an edge of the crystal element 11 or extended up to a region exceeding the edge of the crystal element 11. This embodiment disposes the first wiring electrode 23 up to the edge of the base 21 exceeding the edge of the crystal element 11. The extension of a part of the first wiring electrode 23 to the direction opposite from the second wiring electrode 25 causes this extended part to function as a receiver in the case where the crystal element 11 inclines to this opposite direction. This ensures a reduction in inclination and therefore is preferable.

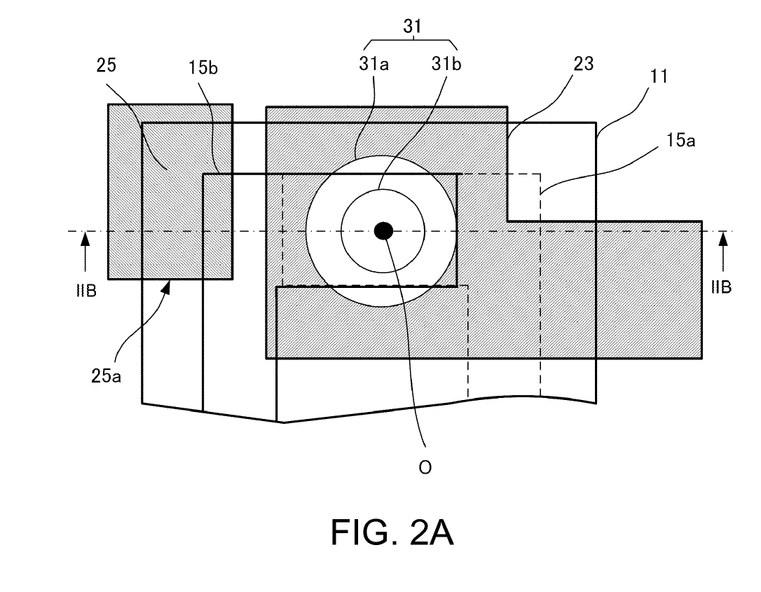

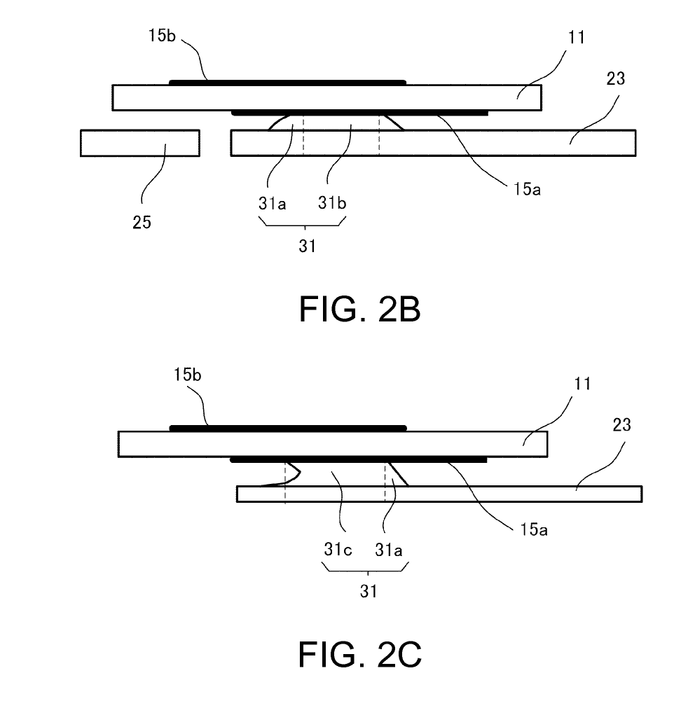

Further, as illustrated in FIG. 1A to FIG. 2C, this first wiring electrode 23 has a planar shape and a size so as to planarly encompass at least a region 31b (the main region 31b for conductive adhesive), which is formed by projecting a part where the conductive adhesive 31 contacts the crystal element 11 to the base 21 side. With a size and an arrangement with which the first wiring electrode 23 encompasses only the main region 31b for conductive adhesive, the object of the disclosure can also achieved. However, forming the first wiring electrode 23 having a planar shape and a size with which an entire applied region 31a for conductive adhesive is planarly encompassed is more preferable. This embodiment describes the example.

Meanwhile, the second wiring electrode 25 is disposed at an end part on the one side 21b side of the base 21 inside the concave portion 21a in the base 21 and near the corner of the concave portion 21a in the base 21. Additionally, an edge 25a on a center side of the base of this second wiring electrode 25 projects out at a size and an arrangement up to a center position O of the entire applied region 31a or the main region 31b for the conductive adhesive 31 or up to the center side of the base 21 with respect to the center position O in a direction perpendicular to the one side 21b, that is, a direction along the long side of the base 21 in this example. In details, the second wiring electrode 25 is disposed on the base 21 such that the edge 25a on the center side of the base of the second wiring electrode 25 projects out to the long side direction of the base 21 with respect to the center position O of the bonded region for the conductive adhesive 31 by a dimension d (see FIG. 1A) to the center side of the base 21. In the case where this projecting position is identical to the center position O of the bonded region, this dimension d is zero. It is preferable that this dimension d be a dimension up to the end on the base center side of the main region 31b for the conductive adhesive. It is more preferable that this dimension d be a dimension up to the end on the base center side of the entire applied region 31a for the conductive adhesive.

The end part of the second wiring electrode 25 on the corner side of the base 21 may contact or be away from the wall part of the base 21. The position of the end part on this corner side may be appropriately determined considering ease of connection of a wire or a similar factor. The first wiring electrode 23 and the second wiring electrode 25 can be constituted of films made of any given preferable materials, for example, an electroless plating film made of, for example, nickel and gold.

As already known, the above-described first wiring electrode 23 and second wiring electrode 25 are each connected to external mounting terminals (not illustrated) disposed at the outer bottom surface of the base 21 with via wirings (not illustrated).

The following describes actions and effects of the piezoelectric device 10 of the embodiment with reference to FIG. 2A and FIG. 2B. FIG. 2A is a plan view mainly illustrating a relationship between the first wiring electrode 23, the second wiring electrode 25, the entire applied region 31a and the main region 31b for the conductive adhesive, and the crystal element 11. FIG. 2B is a sectional drawing of this part taken along the line IIB-IIB in FIG. 2A. For clarification of the first wiring electrode 23 and the second wiring electrode 25, the plan view in FIG. 2A hatches the first wiring electrode 23 and the second wiring electrode 25.

In the piezoelectric device 10 of this embodiment, the main region 31b for the conductive adhesive is planary encompassed in the region of the first wiring electrode 23. Moreover, the entire applied region 31a for the entire conductive adhesive is also planary encompassed inside the region of the first wiring electrode 23. Accordingly, since the conductive adhesive 31 is disposed only on the first wiring electrode 23, the crystal element 11 placed on this conductive adhesive and pressed by a mounting tool or a similar tool is less likely to incline, ensuring improving a problem of the inclination of the crystal element 11. The edge 25a of the second wiring electrode 25 on the center side of the base 21 projects to the center side of the base 21 with respect to the center position O of the conductive adhesive 31. This part plays a role of restricting a degree of inclination of the crystal element 11; therefore, this also causes the crystal element 11 to be less likely to incline. The first wiring electrode 23 extends up to a wall of the base also on a side opposite from the second wiring electrode 25, also ensuring restricting the degree of inclination.

The main region for the conductive adhesive is not limited to the part formed in the convex entire applied region 31a illustrated in FIG. 2B. For example, as illustrated in FIG. 2C, assume the case where the conductive adhesive comes out from the original applied position or a similar case and therefore the conductive adhesive is absent below the part at which the conductive adhesive contacts the crystal element. A region 31c, which is formed by projecting the part at which the conductive adhesive contacts the crystal element to the below, is included in the main region for the conductive adhesive according to this disclosure.

### 2. Embodiment of Base

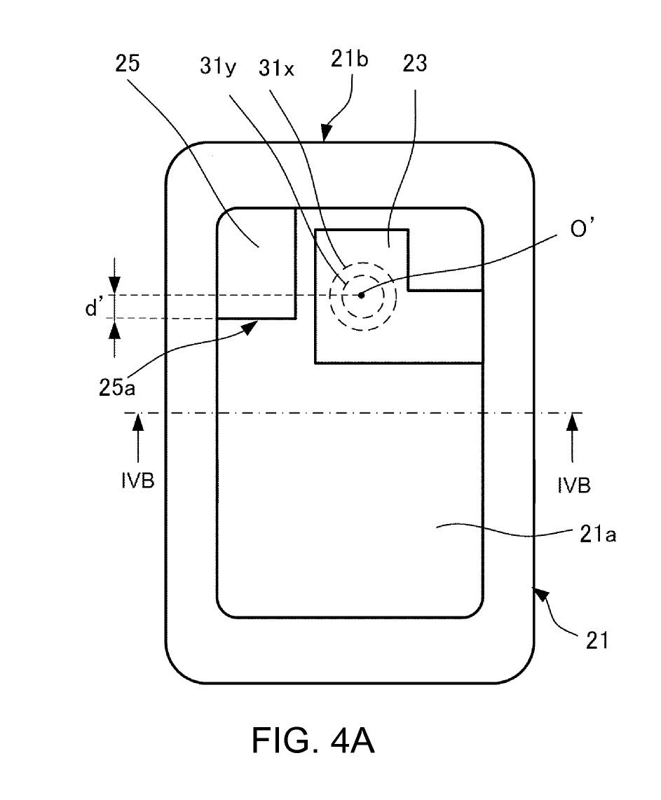

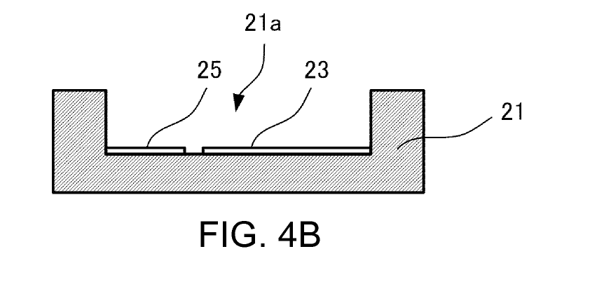

FIG. 4A is a plan view describing the base 21 according to the embodiment, and FIG. 4B is a sectional drawing taken along the line IVB-IVB in FIG. 4A.

The base 21 of the embodiment includes the concave portion 21a for mounting the crystal element. Furthermore, the base 21 includes the first wiring electrode 23 and the second wiring electrode 25. Over the first wiring electrode 23, the conductive adhesive (not illustrated) to securely and electrically connect an end part of one principal surface of the crystal element (not illustrated) to the base is applied. To the second wiring electrode 25, a wire-bonding wire (not illustrated) is connected from an end part of the other surface of the crystal element (not illustrated). The first wiring electrode 23 is disposed at the end part on the one side 21b side of the base 21 inside the concave portion 21a in the base 21 and a part that includes a part corresponding to a center in a direction along the one side 21b. Moreover, the first wiring electrode 23 has a planar shape and a size with which the first wiring electrode 23 planary encompasses at least an expected region 31y at which the conductive adhesive contacts the crystal element in an application-expected region 31x for the conductive adhesive. Preferably, the first wiring electrode 23 has a planar shape and a size with which the first wiring electrode 23 planary encompasses the application-expected region 31x for the conductive adhesive. This case has the latter structure.

The second wiring electrode 25 is disposed at the end part on the one side 21b side of the base 21 inside the concave portion 21a in the base 21 and near the corner of the concave portion 21a in the base 21. Additionally, the edge 25a, which is on the center side of the base of this second wiring electrode 25, is disposed inside the concave portion 21a of the base 21 projecting out at a size and an arrangement up to a center position O′ of the application-expected region 31x or the expected region 31y for the conductive adhesive 31 or up to the center side of the base 21 with respect to the center position O′ in the direction perpendicular to the one side 21b. A dimension d′ indicates how extent that the edge 25a on the center side of the base of the second wiring electrode 25 projects with respect to the center position O′ of the bonding-expected region for the conductive adhesive. It is preferable that the dimension d′ be a dimension up to the end on the base center side of the application-expected region 31x. It is more preferable that the dimension d′ be a dimension up to the end on the center side of the base of the entire application-expected region 31x for the conductive adhesive.

### 3. Other Embodiments

### 3-1. Embodiments that Provide Oscillator Circuit

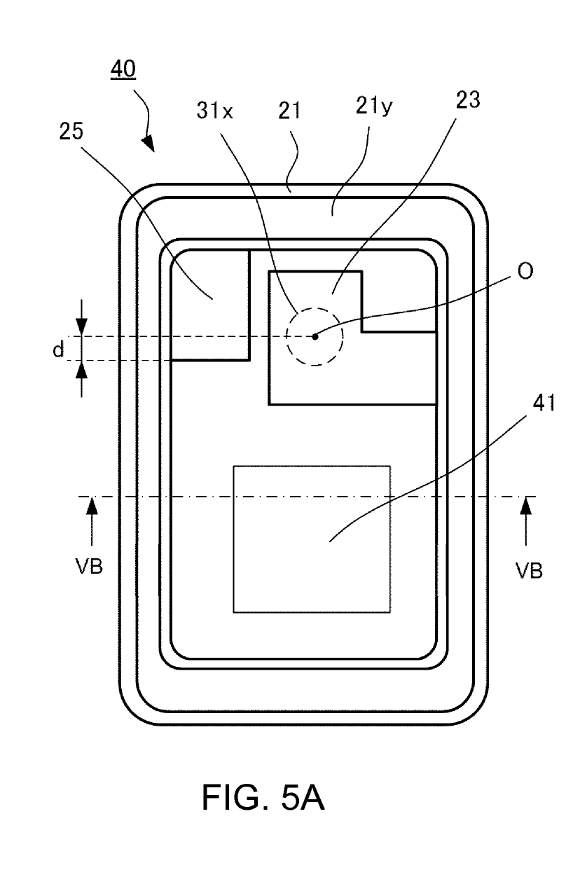

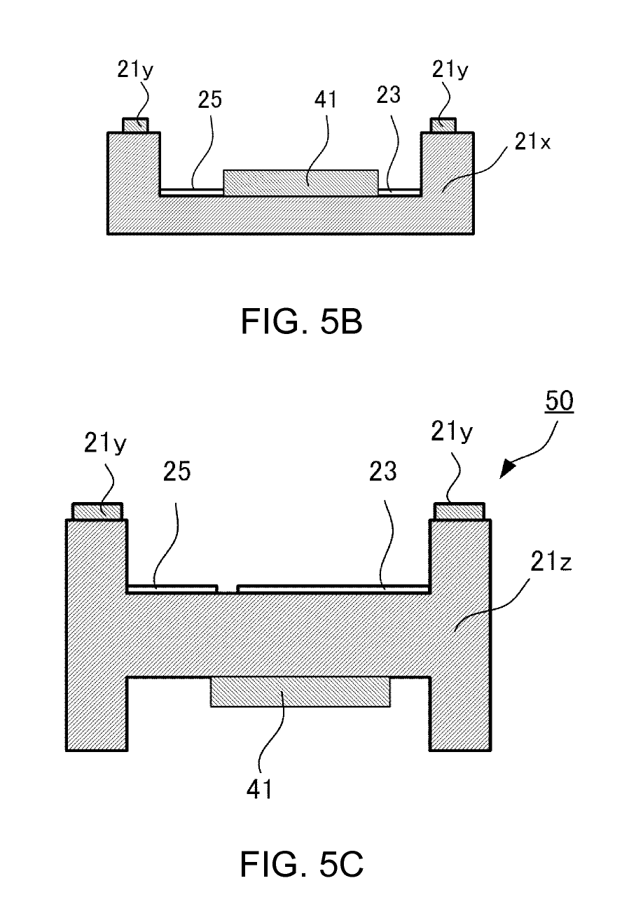

FIG. 5A to FIG. 5C are drawings describing other embodiments. Especially, FIG. 5A is a plan view illustrating an outline of an oscillator 40 having a crystal oscillation circuit 41 of the embodiment, and FIG. 5B is a sectional drawing taken along the line VB-VB in FIG. 5A. FIG. 5C is a sectional drawing illustrating an outline of an oscillator 50 having a so-called H-shaped structure, which has a shape to house a crystal element and components for an oscillator circuit, for example, an IC chip for oscillator circuit in different chambers.

As a sealing method for base, any given method such as a so-called direct seam sealing method, a seam sealing with ring method, and a sealing method with a eutectic alloy material using gold tin and a similar material can be employed. Bases 21x and 21z illustrated in FIG. 5B and FIG. 5C are examples of including rings 21y for seam welding on a bank portion surrounding the concave portion 21a.

### 3-2. Another Example of First Wiring Electrode and Second Wiring Electrode

As illustrated in FIG. 1A and FIG. 1B, the above-described embodiment describes the example that extends the first wiring electrode 23 from the position below the crystal element 11 to the outer region of the crystal element exceeding the edge of the crystal element 11 and extends the second wiring electrode 25 up to the lower side of the crystal element 11. However, as long as the minimum necessary configuration of this disclosure where the first wiring electrode encompasses the application-expected region for the conductive adhesive can restrain the inclination of the crystal element, it is preferable that the first wiring electrode and the second wiring electrode have a minimum necessary planar shape to avoid an unnecessary contact of the first wiring electrode and the second wiring electrode with the crystal element. The embodiment of this section is an example of this configuration.

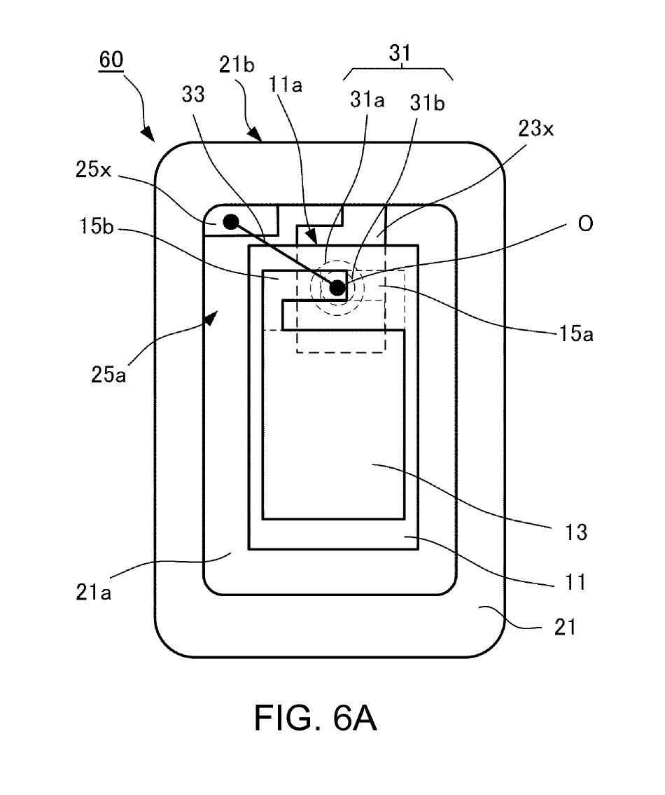

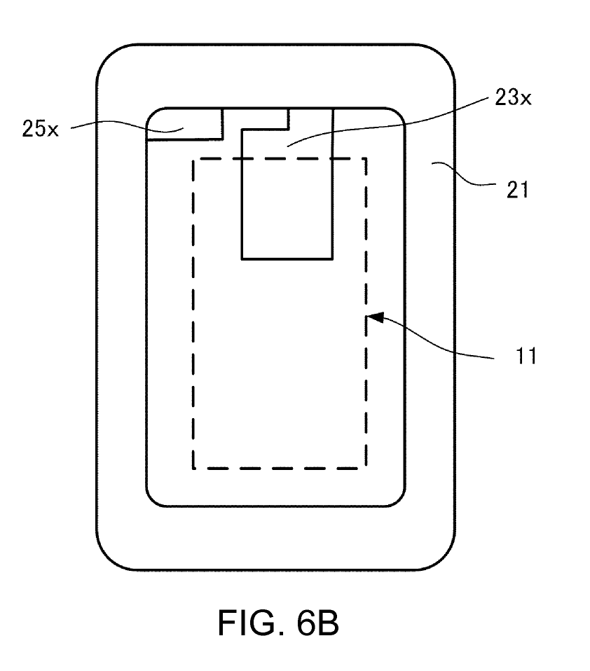

FIG. 6A and FIG. 6B explain the example, especially FIG. 6A is a plan view of a piezoelectric device 60 of this embodiment, and FIG. 6B is a plan view focusing on a first wiring electrode 23x and a second wiring electrode 25x.

The piezoelectric device 60 of this embodiment includes the first wiring electrode 23x at an end part along the one side 11a of the crystal element 11, that is, in a region not exceeding the long side of the crystal element 11. The second wiring electrode 25x is disposed at a region near the corner of the base 21 and not overlapping the crystal element 11, that is, the second wiring electrode 25x does not reach below the crystal element 11 to avoid the overlap with the crystal element 11. Moreover, an extracted direction of the first wiring electrode 23x is configured on the one side 21b side of the base 21. Additionally, an extracted portion of the first wiring electrode 23x is configured at a position close to one side of the first wiring electrode 23x along the one side 11a (the short side) of the crystal element 11. This embodiment is an example where the second wiring electrode 25x is disposed along the one side 11a (the short side) of the crystal element 11. Here, the above-described region of the first wiring electrode 23x not exceeding the long side of the crystal element 11 is a region wider than the entire applied region 31a for the conductive adhesive and is a region not reaching the long side of the crystal element. Preferably, this region is a region wider than the entire applied region 31a for the conductive adhesive and is a region not reaching the long side of the crystal element as much as possible (namely, as narrow as possible). This configuration easily prevents the unnecessary contact of the crystal element with the first wiring electrode.

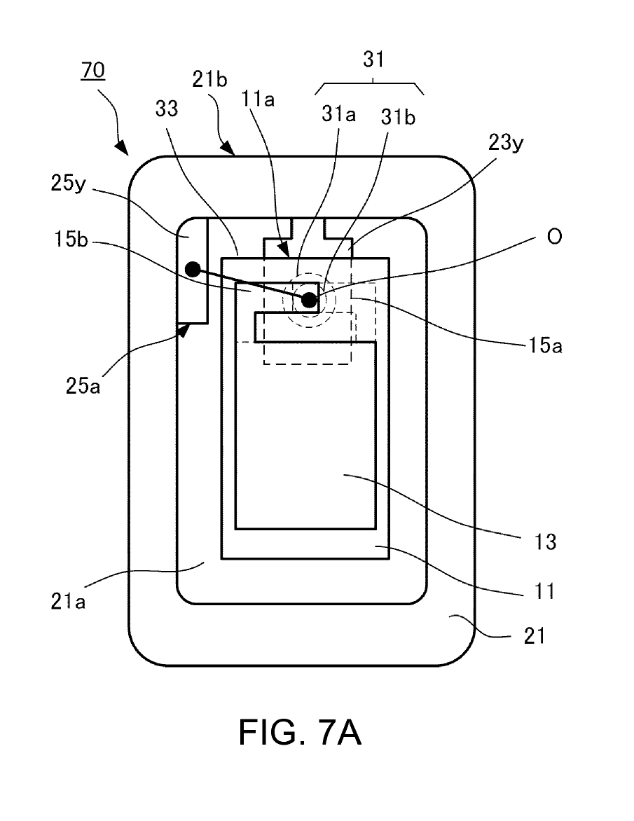

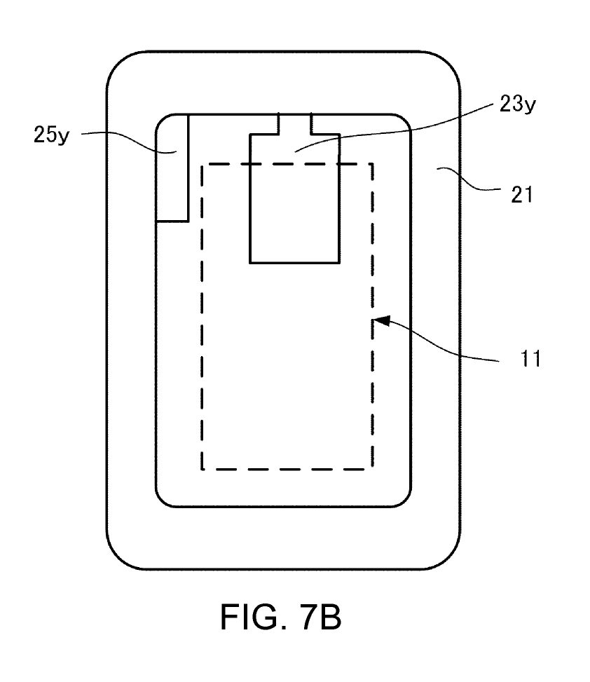

FIG. 7A and FIG. 7B are explanatory drawings for yet another example, especially FIG. 7A is a plan view of a piezoelectric device 70 of this embodiment, and FIG. 7B is a plan view focusing on a first wiring electrode 23y and a second wiring electrode 25y.

Differences between this piezoelectric device 70 and the piezoelectric device 60 are as follows. The second wiring electrode 25y is disposed along the long side of the crystal element 11. An extracted portion of the first wiring electrode 23y is at a center of the first wiring electrode 23y in a direction along the one side 11a (the short side) of the crystal element 11.

### 3-3. Another Embodiment Regarding Base

For example, as illustrated in FIG. 1A and FIG. 1B, the above-described embodiment describes the example where the base, 21 includes the concave portion 21a, which encapsulates the crystal element 11, and the bank portion, which are disposed surrounding the concave portion 21a, and the piezoelectric device is sealed with the lid member at the bank portion. However, the respective aspects of this application may employ a base with another structure. The embodiment in this section is the example.

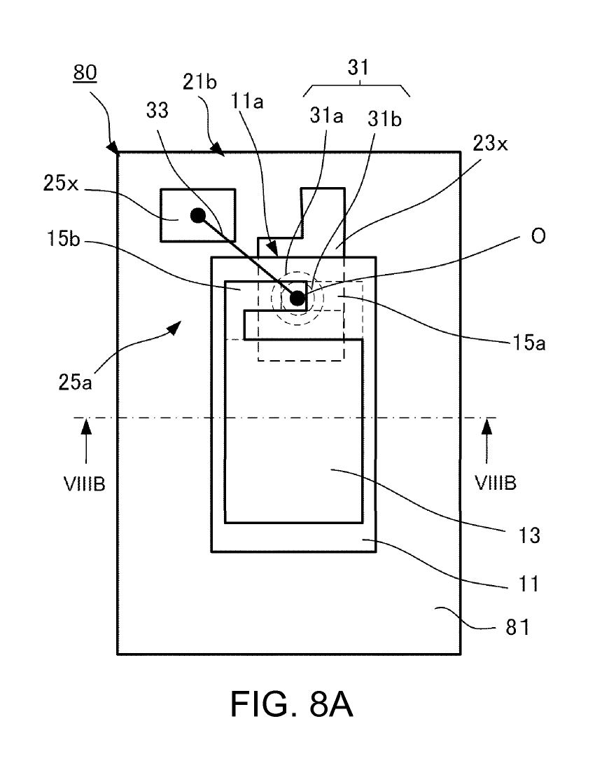

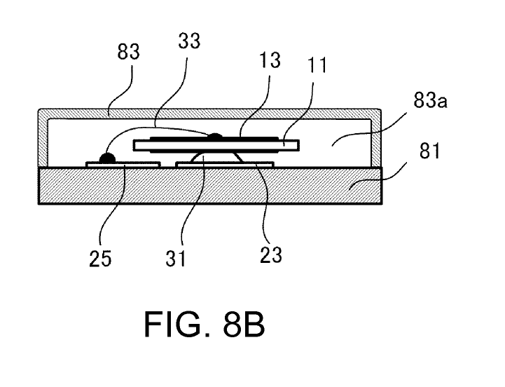

FIG. 8A and FIG. 8B are drawings for the explanation, especially FIG. 8A is a plan view of a piezoelectric device 80 of an embodiment that employs the base with the other structure, and FIG. 8B is a sectional drawing taken along the line VIIIB-VIIIB in FIG. 8A.

The piezoelectric device 80 of this embodiment includes a flat-plate-shaped base 81 and a lid member 83. The base 81 places the crystal element 11 and is provided with the first wiring electrode 23x and the second wiring electrode 25x. The lid member 83 has a concave portion 83a that encapsulates the crystal element 11. In this piezoelectric device 80, the base 81 is sealed with the lid member 83 at the edges (FIG. 8B). The flat-plate-shaped base 81 can be made of, for example, ceramics. The lid member 83 can be made of, for example, a metallic member formed by drawing process. Any given preferable method may be employed as a sealing method of the base 81 with the lid member 83. For example, the following method can be employed. Eutectic alloys (not illustrated) are provided on the edges of the base 81 to bond the lid member 83 with the eutectic alloys. Alternatively, a method that connects the edges of the base 81 to the lid member 83 with a material such as an adhesive can be employed.

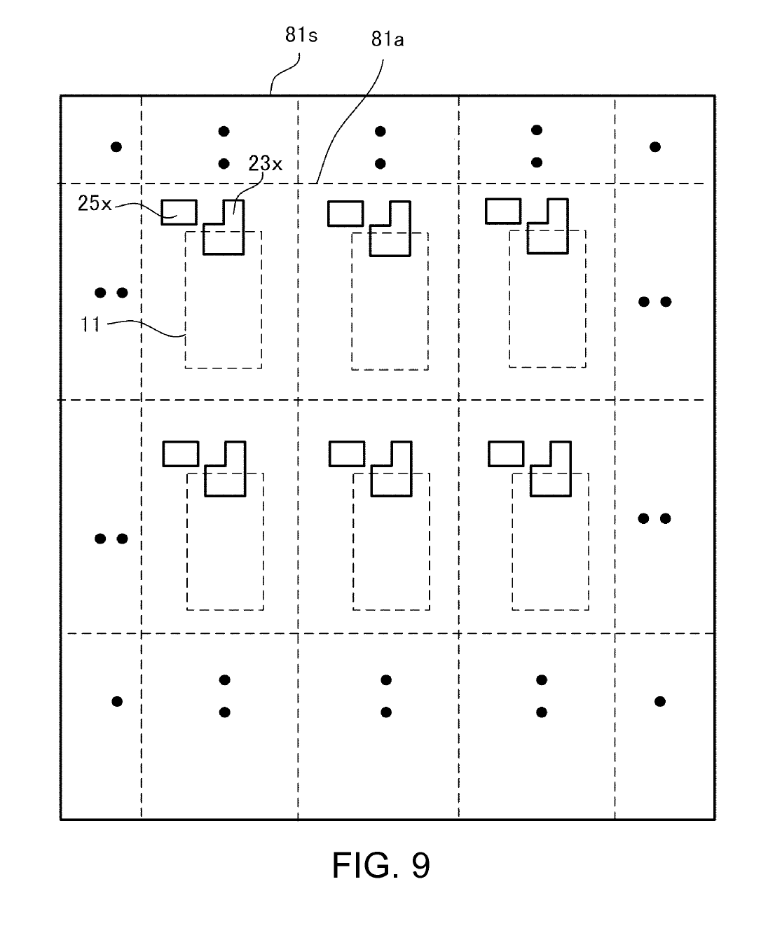

As illustrated in FIG. 9, this base 81 is typically formed of a sheet-shaped base member 81s that includes regions 81a. The regions 81a are divided such that the crystal elements 11 to be implemented can be placed and a large count of the crystal elements 11 are equipped. Specifically, a large number of piezoelectric devices are assembled using the sheet-shaped base member 81s. Afterwards, this sheet-shaped base member 81s is individually chipped into the respective devices through dicing or a similar method, thus fabricating the piezoelectric devices 80.

To achieve this disclosure, a piezoelectric device according to a first aspect of this application includes a crystal element with a rectangular planar shape, excitation electrodes, extraction electrodes, a base, and a first wiring electrode and a second wiring electrode. The excitation electrodes are disposed on respective principal surfaces of the crystal element. The extraction electrodes are extracted from the respective excitation electrodes up to near one side of the crystal element. The base has a rectangular planar shape on which the crystal element is mounted. The first wiring electrode and the second wiring electrode are disposed on the base. The first wiring electrode and the second wiring electrode are connected to the extraction electrodes.

Additionally, the crystal element is connectedly secured to the first wiring electrode with a conductive adhesive at an end part at a side of the one side on one principle surface of the crystal element. The extraction electrode on the other principle surface of the crystal element and the second wiring electrode are connected by a wire bonding. The connectedly secured and the wire bonding are performed such that a secured position with the conductive adhesive overlaps a bonding position on a side of the crystal element by the wire bonding in a crystal element thickness direction (includes the case where the secured position and the bonding position almost overlap).

Additionally, the first wiring electrode is disposed at an end part at a side of one side of the base. The first wiring electrode has a planar shape and a size so as to planarly encompass at least a region (hereinafter also referred to as a main region for conductive adhesive). The region is formed by projecting a part where the conductive adhesive that is used for the connectedly secured contacts the crystal element to the base side. The first wiring electrode has a surface as flat as possible.

To embody this first aspect, the following is preferable. The first wiring electrode is disposed at the end part at a side of the one side of the base. The first wiring electrode is disposed at a part including a part corresponding to a center in a direction along the one side.

To embody this first aspect, the following is more preferable. The first wiring electrode has the size and the planar shape with which an entire applied region for the fixing conductive adhesive is planarly encompassed.

According to this first aspect and the preferable examples, the conductive adhesive for securing the crystal element is positioned on the first wiring electrode having a plane area wider than a plane area of the main region. The absence of a level difference on an applied surface of the conductive adhesive draws the crystal element to a lower level side after the crystal element is mounted and before the conductive adhesive hardens. Additionally, pressing the crystal element from the above causes an inclination of the crystal element and a variation in height. However, with this disclosure, at least the main region for the conductive adhesive does not protrude from the first wiring electrode and is not disposed across the base but is disposed only on the surface at the identical height. This ensures reducing the inclination of the crystal element and the variation in height.

To embody the first aspect of this application, it is preferable to configure the above-described first wiring electrode and second wiring electrode to be the following respective configurations (a) to (d) and to be one configuration among or a configuration of plural combinations of these (a) to (d) according to the object.

(a) One configuration is as follows. The first wiring electrode and the second wiring electrode are disposed in a direction along the one side of the crystal element. The first wiring electrode extends up to a region exceeding an end part along the one side of the crystal element in a direction opposite from a side of the second wiring electrode (The concrete example is the first wiring electrode 23 in FIG. 1A and FIG. 1B).

(b) One configuration is as follows. The first wiring electrode and the second wiring electrode are disposed in a direction along the one side of the crystal element. The second wiring electrode is disposed near a corner of the base. An edge on a center side of the base of the second wiring electrode is disposed at a size and an arrangement to be a center position of a bonded region with the fixing conductive adhesive or the center side of the base with respect to the center position in a direction perpendicular to the one side (The concrete example is the second wiring electrode 25 in FIG. 1A and FIG. 1B).

(c) One configuration is as follows. The first wiring electrode and the second wiring electrode are disposed in a direction along the one side of the crystal element. The first wiring electrode is disposed in a region that does not exceed an end part along the one side of the crystal element (The concrete example is the first wiring electrode 23x in FIG. 6A and FIG. 6B and the first wiring electrode 23y in FIG. 7A and FIG. 7B).

(d) One configuration is as follows. The first wiring electrode and the second wiring electrode are disposed in a direction along the one side of the crystal element. The second wiring electrode is disposed near a corner of the base and at a region where the second wiring electrode does not overlap the crystal element (The concrete example is the second wiring electrode 25x in FIG. 6A and FIG. 6B and the second wiring electrode 25y in FIG. 7A and FIG. 7B).

The use of any one of or both of the configuration (a) and the configuration (b) causes the first wiring electrode and/or the second wiring electrode to act also as (a) member(s) to reduce the inclination of the crystal element. This ensures assisting the correction in case that the crystal element inclines.

The use of any one of or both of the above-described configuration (c) and configuration (d) provides the first wiring electrode and the second wiring electrode with the planar shape meeting the minimum requirements of this first aspect, which are the size and the planar shape to the extent that the entire applied region for the conductive adhesive is planary encompassed. That is, the first wiring electrode and the second wiring electrode are present at only the required regions below the crystal element but are absent below the edge of the crystal element. In view of this, assume the case where the inclination of the crystal element is prevented with the minimum necessary constitutions of the first aspect that the first wiring electrode and the second wiring electrode have the size and the planar shape with which the entire applied region for the conductive adhesive is planary encompassed. Then, even if a slight inclination to the extent of not contacting the bottom surface of the base remains, these constitutions ensure preventing the edge of the crystal element from contacting the first wiring electrode and the second wiring electrode. This allows eliminating an influence of stress to the crystal element caused by such unnecessary contact. Accordingly, the configurations (c) and (d) are effective to the piezoelectric device, which is likely to be affected by the stress.

As the conductive adhesive used for the first aspect and the preferable examples, various conductive adhesives such as silicone-based, epoxy-based, and polyimide-based conductive adhesives are applicable. However, to embody this disclosure, it is preferable to use a conductive adhesive with rich elasticity, typically to use the silicone-based conductive adhesive. Since this enhances a buffering effect between the crystal element and the base compared with the case of the use of the epoxy-based and the polyimide-based conductive adhesives, thereby ensuring further reducing an influence of stress from the base.

The piezoelectric device according to the second aspect of this application is configured as follows. The piezoelectric device is any one of the piezoelectric device according to the above-described first aspect and the preferable examples. The piezoelectric device further includes a crystal oscillation circuit, being mounted to the base together with the crystal element. This second aspect ensures achieving a crystal controlled oscillator of no property deterioration caused by the inclination of the crystal element.

The disclosure of the base according to the third aspect of this application is configured as follows. A base with a rectangular planar shape includes a first wiring electrode and a second wiring electrode. Over the first wiring electrode, conductive adhesive to securely and electrically connect an end part of one principal surface of a crystal element to the base is applied. To the second wiring electrode, a wire-bonding wire is connected from an end part of the other surface of the crystal element. The first wiring electrode is disposed at an end part at a side of one side of the base. The first wiring electrode has a size and a planar shape with which the first wiring electrode planary encompasses at least an expected region (the expected region that becomes the main region for the conductive adhesive). The region is formed by projecting a part where the applied conductive adhesive contacts the crystal element to the base side.

To embody the disclosure of this base, like the preferable examples of the first aspect described above, the following is more preferable. The first wiring electrode is disposed at the end part at a side of the one side of the base. The first wiring electrode is disposed at the part corresponding to the center in the direction along the one side. The first wiring electrode may be configured as follows. The first wiring electrode has a size and a planar shape with which the first wiring electrode planary encompasses the entire application-expected region for the fixing conductive adhesive.

Furthermore, to embody the disclosure of this base, it is preferable to configure the base to be one configuration among or a configuration of plural combinations of these (a) to (d) configurations described in the above-described first aspect.

The disclosure of this base and the preferable examples ease manufacturing the piezoelectric device with the one-site holding structure that uses both the conductive adhesive and the wire bonding.

With the piezoelectric device according to the embodiment of this application, the piezoelectric device with one-site holding structure employing both the conductive adhesive and the wire bonding featuring small inclination of the crystal element and variation in height of the crystal element can be obtained.

With the disclosure of the base of this application, the above-described disclosure of the piezoelectric device is easily embodied.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a crystal element with a rectangular planar shape;
excitation electrodes, being disposed on respective principal surfaces of the crystal element;
extraction electrodes, being extracted from the respective excitation electrodes up to near one side of the crystal element;
a base with a rectangular planar shape on which the crystal element is mounted; and
a first wiring electrode and a second wiring electrode, being disposed on the base, and the first wiring electrode and the second wiring electrode being connected to the extraction electrodes, wherein
the crystal element is connectedly secured to the first wiring electrode with a conductive adhesive at an end part at a side of the one side on one principal surface of the crystal element,
the extraction electrode on another principal surface of the crystal element and the second wiring electrode are connected by a wire bonding,
the connectedly secured and the wire bonding are performed such that a secured position with the conductive adhesive overlaps a bonding position on a side of the crystal element by the wire bonding in a crystal element thickness direction, and
the first wiring electrode is disposed at an end part at a side of one side of the base and has a planar shape and a size so as to planarly encompass at least a region formed by projecting a part where the conductive adhesive contacts the crystal element to a side of the base.

2. The piezoelectric device according to claim 1, wherein
the first wiring electrode is disposed at the end part at a side of the one side of the base, and
the first wiring electrode being disposed at a part including a part corresponding to a center in a direction along the one side.

3. The piezoelectric device according to claim 1, wherein
the first wiring electrode has the size and the planar shape with which an entire applied region for the conductive adhesive that is used for the connectedly secured is planarly encompassed.

4. The piezoelectric device according to claim 1, wherein
the first wiring electrode and the second wiring electrode are disposed in a direction along the one side of the crystal element, and
the first wiring electrode extends up to a region exceeding an end part along the one side of the crystal element in a direction opposite from a side of the second wiring electrode.

5. The piezoelectric device according to claim 1, wherein
the first wiring electrode and the second wiring electrode are disposed in a direction along the one side of the crystal element, and
the second wiring electrode is disposed near a corner of the base, and an edge on a center side of the base of the second wiring electrode being disposed at a size and an arrangement to be a center position of a bonded region with the conductive adhesive that is used for the connectedly secured or the center side of the base with respect to the center position in a direction perpendicular to the one side.

6. The piezoelectric device according to claim 1, wherein
the first wiring electrode and the second wiring electrode are disposed in a direction along the one side of the crystal element,
the first wiring electrode extends up to a region exceeding an end part along the one side of the crystal element in a direction opposite from a side of the second wiring electrode, and
the second wiring electrode is disposed near a corner of the base, and an edge on a center side of the base of the second wiring electrode being disposed at a size and an arrangement to be a center position of a bonded region with the conductive adhesive that is used for the connectedly secured or the center side of the base with respect to the center position in a direction perpendicular to the one side.

7. The piezoelectric device according to claim 1, wherein
the first wiring electrode and the second wiring electrode are disposed in a direction along the one side of the crystal element, and
the first wiring electrode is disposed in a region that does not exceed an end part along the one side of the crystal element in a direction opposite from a side of the second wiring electrode.

8. The piezoelectric device according to claim 1, wherein
the first wiring electrode and the second wiring electrode are disposed in a direction along the one side of the crystal element, and
the second wiring electrode is disposed near a corner of the base and at a region where the second wiring electrode does not overlap the crystal element.

9. The piezoelectric device according to claim 1, wherein
the first wiring electrode and the second wiring electrode are disposed in a direction along the one side of the crystal element,
the first wiring electrode is disposed in a region that does not exceed an end part along the one side of the crystal element, and
the second wiring electrode is disposed near a corner of the base and at a region where the second wiring electrode does not overlap the crystal element.

10. The piezoelectric device according to claim 1, wherein
the base includes a concave portion and a bank portion surrounding the concave portion, the concave portion encapsulating the crystal element, and
the piezoelectric device is sealed with a lid member at the bank portion.

11. The piezoelectric device according to claim 1, wherein
the base has a flat plate shape to place the crystal element, and
the piezoelectric device is sealed with a lid member, and the lid member having a concave portion to encapsulate the crystal element.

12. The piezoelectric device according to claim 1, wherein
the conductive adhesive is silicone-based conductive adhesive.

13. The piezoelectric device according to claim 1, further comprising:
a crystal oscillation circuit, being mounted to the base together with the crystal element.

14. A base with a rectangular planar shape, comprising:
a first wiring electrode on which a conductive adhesive is applied, and the conductive adhesive securely and electrically connecting an end part of one principal surface of a crystal element to the base; and
a second wiring electrode to which a wire-bonding wire is connected from an end part of another principal surface of the crystal element, wherein
the first wiring electrode is disposed at an end part at a side of one side of the base and a part that includes a part corresponding to a center in a direction along the one side, and
the first wiring electrode having a size and a planar shape with which the first wiring electrode planary encompasses at least an expected region, the conductive adhesive contacting the crystal element at the expected region in an application-expected region for the conductive adhesive.

15. The base according to claim 14, wherein
the first wiring electrode is disposed at the end part at a side of the one side of the base, and
the first wiring electrode being disposed at the part corresponding to the center in the direction along the one side, and
the first wiring electrode having a size and a planar shape with which the first wiring electrode planary encompasses the entire application-expected region for the conductive adhesive that is used for the securely and electrically connecting.

16. The base according to claim 14, wherein
the first wiring electrode and the second wiring electrode are disposed in a direction along the one side, and
the first wiring electrode extends up to a region exceeding an end part along the one side of the crystal element to be mounted in a direction opposite from a side of the second wiring electrode.

17. The base according to claim 14, wherein
the first wiring electrode and the second wiring electrode are disposed in a direction along the one side, and
the second wiring electrode has an edge on a center side of the base at an end part at a side of the one side and at a part corresponding to a corner of the base, and the edge having a size and an arrangement projecting out to a center position of a application-expected region for the conductive adhesive or to a center side of the base with respect to the center position in a direction perpendicular to the one side.

18. The base according to claim 14, wherein
the first wiring electrode and the second wiring electrode are disposed in a direction along the one side,
the first wiring electrode extends up to a region exceeding an end part along the one side of the crystal element to be mounted in a direction opposite from a side of the second wiring electrode, and
the second wiring electrode has an edge on a center side of the base at an end part at a side of the one side and at a part corresponding to a corner of the base, and the edge having a size and an arrangement projecting out to a center position of a application-expected region for the conductive adhesive or to a center side of the base with respect to the center position in a direction perpendicular to the one side.

19. The base according to claim 14, wherein
the first wiring electrode and the second wiring electrode are disposed in a direction along the one side, and
the first wiring electrode is disposed in a region that does not exceed an end part along the one side of the crystal element to be mounted.

20. The base according to claim 14, wherein
the first wiring electrode and the second wiring electrode are disposed in a direction along the one side, and
the second wiring electrode is disposed near a corner of the base and at a region where the second wiring electrode does not overlap the crystal element to be mounted.
